(19) United States
(12) Patent Application Publication
(10) Pub. No.: US 2018/0212199 A1
(43) Pub. Date: Jul. 26, 2018

(54) BOTTOM-EMITTING OLED DISPLAY UNIT AND METHOD FOR MANUFACTURING THE SAME

(71) Applicant: Wuhan China Star Optoelectronics Technology Co., Ltd., Wuhan, Hubei (CN)

(72) Inventor: Wei Yu, Wuhan, Hubei (CN)

(73) Assignee: Wuhan China Star Optoelectronics Technology Co., Ltd., Wuhan, Hubei (CN)

(21) Appl. No.: 15/327,130

(22) PCT Filed: Dec. 28, 2016
(86) PCT No.: PCT/CN2016/112720

§ 371 Date: Jan. 18, 2017

(30) Foreign Application Priority Data
Dec. 26, 2016 (CN) 201611217655.X

(51) Int. Cl. H01L 51/52; H01L 51/00; H01L 27/32; H01L 51/56

(52) U.S. Cl. CPC H01L 51/5275; H01L 51/0096; H01L 27/3262; H01L 27/1248; H01L 51/56; H01L 27/3272; H01L 2251/5307; H01L 27/3258

(57) ABSTRACT

Disclosed are a bottom-emitting OLED display unit and a method for manufacturing the same. In the bottom-emitting OLED display unit, thin film transistor structures are disposed on a transparent substrate, an interlayer insulating layer and a planarization layer are disposed above the thin film transistor structures, and a light-extracting layer is disposed between the interlayer insulating layer and the planarization layer. The light-extracting layer is configured such that the light projected on a surface thereof is deflected. By means of the bottom-emitting OLED display unit, light extraction efficiency of the OLED display device can be improved, thereby increasing brightness of a display image.

### CROSS-REFERENCE TO RELATED APPLICATIONS

The present application claims the priority of Chinese patent application CN201611217655.X, entitled “Bottom-emitting OLED Display Unit and Method for Manufacturing the Same” and filed on Dec. 26, 2016, the entirety of which is incorporated herein by reference.

### FIELD OF THE INVENTION

The present disclosure relates to the field of display technologies, and in particular, to a bottom-emitting OLED display unit and a method for manufacturing the same.

### BACKGROUND OF THE INVENTION

An OLED display device is a new generation of display devices, and has many advantages, such as self-luminescence, fast response, wide viewing angle and saturated color, as compared with a liquid crystal display device. The OLED display device is mainly formed by an organic thin film provided on an OLED substrate with cathode and anode metals disposed on both sides of the organic thin film. When a voltage is applied to a cathode and an anode with the organic thin film sandwiched therebetween, the organic thin film emits light to form an image display.

At present, there are two types of OLED display device, a bottom-emitting OLED display device (light is emitted downwards relative to the substrate) and a top-emitting OLED display device (light is emitted upwards relative to the substrate). For the top-emitting OLED display device, an anode is used for light reflection, and a cathode is used for light transmission. The microcavity effect needs to be used. Strict requirements are needed for thicknesses of respective film layers, and a manufacturing process of the top-emitting OLED display device is relatively more difficult. For the bottom-emitting OLED display device, an anode is used for light transmission, and a cathode is used for light reflection. Generally, the anode is made of a conventional ITO thin film, and the cathode is made of metals, such as Al, Mg, and Ag. A manufacturing process of the bottom-emitting OLED display device is relatively simple, and thus the bottom-emitting OLED display device is widely applied.

However, in an OLED display device, pixel units each are provided with multiple thin film transistor (TFT) structures for control. Some of the thin film transistor structures are used as switching elements, some are used for current control, and some play a role of a compensation circuit. Presence of multiple TFTs results in a decrease in an aperture ratio of the bottom-emitting OLED display device, so that part of the light emitted from a light-emitting material (organic thin film) of the OLED display device is blocked by the TFTs and thus cannot be output efficiently, thereby reducing light extraction efficiency of the OLED display device, as shown in FIG. 1.

The present disclosure provides solutions to the problem mentioned above.

### SUMMARY OF THE INVENTION

One of the technical problems to be solved by the present disclosure is to reduce the occurrence of light being blocked by thin film transistor structures in a bottom-emitting OLED display device so as to improve light extraction efficiency of art OLED display device.

In order to solve the above technical problem, a bottom-emitting OLED display unit is first provided in embodiments of the present application. The bottom-emitting OLED display unit comprises a transparent substrate, a plurality of thin film transistor structures, disposed on the transparent substrate, for constituting a driving circuit, an interlayer insulating layer and a planarization layer disposed above the thin film transistor structures, and a light-extracting layer disposed between the interlayer insulating layer and the planarization layer. The light-extracting layer is configured such that light projected on a surface thereof is deflected so as to prevent the light from being blocked by the thin film transistor structures,

Preferably, a refractive index of a material for manufacturing the light-extracting layer is greater than a refractive index of a material for manufacturing the planarization layer.

Preferably, a light transmittance of a material for manufacturing the to light-extracting layer is greater than or equal to a light transmittance of a material for manufacturing the planarization layer.

Preferably, the light-extracting layer is disposed within a region corresponding to a gap between the plurality of thin film transistor structures.

Preferably, the light-extracting layer comprises a light direct-irradiation region and a light refraction region. The light refraction region is located at a periphery of the light direct-irradiation region. A path of light irradiating the light direct-irradiation region does not change or does not change significantly, and a path of light irradiating the light refraction region changes significantly.

Preferably, the light direct-irradiation region has a surface parallel to the planarization layer, and the light refraction region has a surface inclined with respect to the planarization layer.

Preferably, both the light direct-irradiation region and the light refraction region have an arcuate surface.

Preferably, the light-extracting layer is made of an organic material or an inorganic material.

A method for manufacturing the bottom-emitting OILED display unit is also provided in embodiments of the present application. The method comprises following steps: forming, on a transparent substrate, a plurality of thin film transistor structures for constituting a driving circuit; forming an interlayer insulating layer above the thin film transistor structures; forming a material layer above the interlayer insulating layer; patterning the material layer to form a light-extracting layer; and forming a planarization layer above the light-extracting layer.

Preferably, the material layer is patterned with a gray tone mask to form the light-extracting layer.

Compared with the prior art, one or more embodiments of the solution mentioned to above may have following advantages or benefits.

Light extraction efficiency of the OLED display unit is improved by disposing the light-extracting layer between the interlayer insulating layer and the planarization layer of the OLED display unit so as to change a propagation direction of a light path and thereby prevent the light from being blocked by the thin film transistor structures. Accordingly, brightness of a display image is increased, and display effect is improved.

Other advantages, objectives and features of the present disclosure will partly be further explained in the following description, and partly become evident to those skilled in the art based on a study of the following description, or may be taught from implementations of the present disclosure. The objectives and other advantages of the present disclosure will be implemented and achieved through the structures specifically pointed out in the description, claims, and the accompanying drawings.

### BRIEF DESCRIPTION OF THE DRAWINGS

The drawings are provided for further understanding of the technical solutions of the present application or the prior art, and constitute one part of the description. The drawings illustrating embodiments of the present application serve to explain the technical solutions in conjunction with the embodiments of the present application, rather than to limit the technical solution of the present application.

FIG. 1 schematically shows a structure of a bottom-emitting OLED display unit in the prior art;

FIGS. 2 and 3 schematically show cross sections of structures of bottom-emitting OLED display units according to one embodiment of the present disclosure;

FIG. 4 schematically shows a stereogram of a light-extracting layer in the bottom-emitting OLED display unit as shown in FIG. 2;

FIG. 5 schematically shows a stereogram of a light-extracting layer in the bottom-emitting OLED display unit as shown in FIG. 3;

FIG. 6 schematically shows a stereogram of a light-extracting layer in a bottom-emitting OLED display unit of another embodiment; and

FIG. 7 schematically shows a flow chart of a method for manufacturing a bottom-emitting OLED display unit according to another embodiment of the present disclosure.

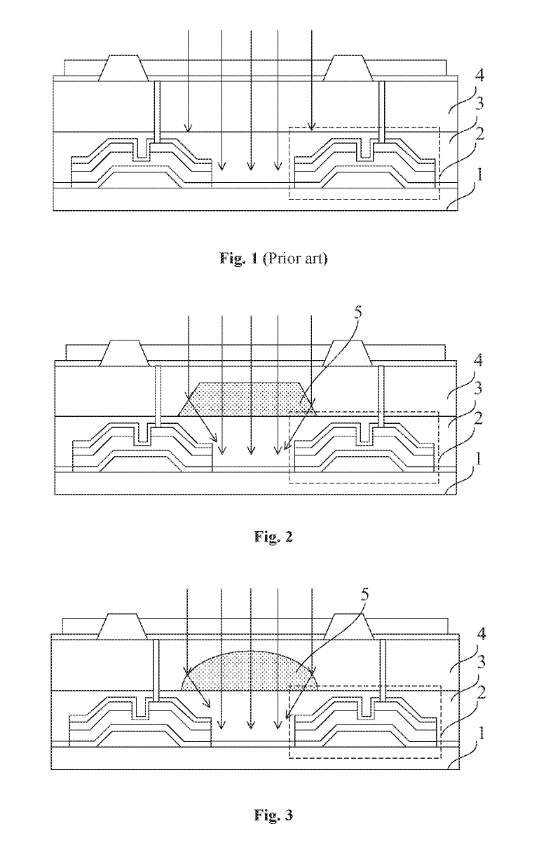

### DETAILED DESCRIPTION OF THE EMBODIMENTS

Implementing manners of the present disclosure will be described in detail with reference to accompanying drawings and embodiments, so that one can fully understand how to solve the technical problem by the technical means according to the present disclosure and achieve the technical effects thereof, and thus the technical solution according to the present disclosure can be implemented. The embodiments of the present application and various features in the embodiments may be combined with one another without conflicts, and the technical solutions obtained in this manner all fall within the scope of the present disclosure.

FIG. 2 schematically shows a cross section of a structure of a bottom-emitting OLED display unit according to one embodiment of the present disclosure. As shown in the figure, the bottom-emitting OLED display unit is provided on a substrate 1, and two thin film transistor structures 2 are illustrative of a plurality of thin film transistors for constituting a driving circuit, and do not constitute a limitation to the present disclosure.

After emitted from a light emitting material layer at a top of the OLED display unit, light exits downwards directly, or exits downwards after being reflected by a reflective electrode which is disposed above the light emitting material layer. At this time, a plurality of thin film transistor structures 2 form a barrier in a propagation path of the light, thereby blocking the

In order to prevent the light from being blocked by the thin film transistor structures 2, a structure capable of changing the propagation path of the light is provided in the present embodiment. Specifically, it is shown in FIG. 2. An interlayer insulating layer 3 and a planarization layer 4 are disposed in order above the thin film transistor structures 2, and a light-extracting layer 5 is disposed between the interlayer insulating layer 3 and the planarization layer 4, so that the light reaching a surface of the light-extracting layer 5 is deflected.

It can be seen from FIG. 2 that the light-extracting layer 5 is located within a region corresponding to a gap between the plurality of thin film transistor structures 2, which facilitates light exiting and improves efficiency of the light-extracting layer. By contrast, although a light-extracting layer which is disposed above the thin film transistor structures 2 may also enable the light that is blocked by the thin film transistor structures 2 to exit again by changing the propagation path of the light, the light that exits is limited in this case, resulting in low light extraction efficiency of the light-extracting layer 5. Therefore, the light-extracting layer which is disposed above the thin film transistor structures 2 is less used considering the production cost.

Further, in embodiments of the present disclosure, the light-extracting layer 5 corresponds to each display unit. That is, light-extracting layers of different OLED display units are separate, so that the light-extracting layer can fully fit wiring of an OLED display panel.

For an OLED display panel having a particular structure, if it is allowed by wiring, light-extracting layers 5 of some display units can be interconnected. For example, light-extracting layers in respective OLED display units corresponding to a same row of pixels can be connected together, or light-extracting layers in respective OLED display units corresponding to a same volume of pixels can be connected together. Those skilled in the art can make various changes and modifications in accordance with the embodiments of the present disclosure without departing from the spirit and essence of the present disclosure.

A material for manufacturing the light-extracting layer 5 is selected such that a refractive index thereof is greater than a refractive index of a material for manufacturing the planarization layer 4.

As shown in FIG. 2, as the refractive index of the material of the light-extracting layer 5 is larger, when the light enters the light-extracting layer 5 from the interface between the planarization layer 4 and the light-extracting layer 5, the propagation path of the light is deflected. It can be known from relevant optical knowledge that the Is light is deflected towards a direction close to an interface normal, so that the light-extracting layer has a light convergence effect.

In the present embodiment, the light-extracting layer 5 is disposed between the interlayer insulating layer 3 and the planarization layer 4, and the light that is blocked by the thin film transistor structures 2 can exit through the gap between the thin film transistor structures 2 by means of the light convergence effect of the light-extracting layer 5, thereby improving light extraction efficiency of the OLED display unit and light utilization efficiency.

Further, if a light transmittance of the material for manufacturing the light-extracting layer 5 is less than a light transmittance of the material for manufacturing for the planarization layer 4, it is possible that the light-extracting layer 5 makes the light reaching a surface thereof be emitted or absorbed, which definitely reduces the light extraction efficiency of the OLED display unit and the light utilization efficiency.

Therefore, in other embodiments of the present disclosure, the light transmittance of the material for manufacturing the light-extracting layer 5 is arranged to be greater than or equal to the light transmittance of the material for manufacturing the planarization layer 4 so as to ensure that the light reaching the surface of the light-extracting layer 5 can exit efficiently.

On the premise that the refractive index and the light transmittance of the material for making the light-extracting layer 5 meet requirements, the light-extracting layer 5 may he made of an organic material or an inorganic material, such as silicon nitride (SiNx), silicon oxide (SiOx), or polyimide, which is not limited in the embodiments of the present disclosure.

Further, the light-extracting. layer 5 of the embodiments of the present disclosure comprises a light direct-irradiation region and a light refraction region. When the light irradiates a surface of the light direct-irradiation region of the light-extracting layer 5, its path does not change or does not change significantly. When the light irradiates a surface of the light refraction region of the light-extracting layer 5, its path changes significantly.

Generally, the light refraction region is located at a periphery of the light direct-irradiation region. As shown in FIG. 2, the light reaching the region between two thin film transistors is not blocked by the thin film transistor structures 2, so that the light direct-irradiation region of the light-extracting layer 5 is generally located at a middle of the whole the light-extracting layer 5. Accordingly, the light reaching the region between two thin film transistor structures can directly exit through the light-extracting layer, and the light path does not change or only changes slightly. By contrast, at positions closer to the thin film transistors, the light is more likely to he blocked, The light refraction region of the light-extracting layer 5 is generally located.

at the periphery of the light direct-irradiation region, and the light emitted towards the light refraction region of the light-extracting layer 5 is refracted, leading to a change in the propagation path. That is, the light path changes significantly.

It should be noted that the significant change herein is determined by those skilled in the art according to common knowledge and actual situations. For example, the light direct-irradiation region and light refraction region can be defined based on the deflection of the propagation path of the light or the refraction angle of the light.

Detailed description is given below in conjunction with structures of the light-extracting layer 5 in specific embodiments.

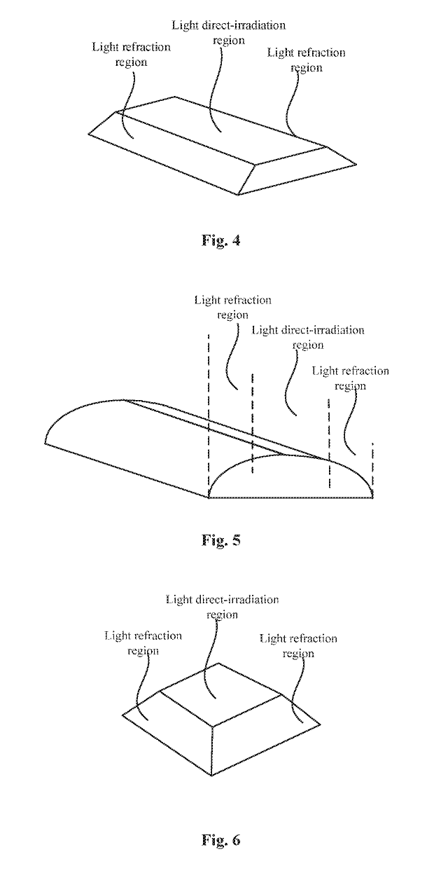

FIG. 4 schematically shows a stereogram of a light-extracting layer in the bottom-emitting OLED display unit shown in FIG. 2. It can be seen that the light-extracting layer 5 in the present embodiment has a trapezoidal cross section, which has a length value in a direction perpendicular to a plane of paper (as shown in FIG. 2), and the length value is determined by a size of the display unit and other structures in the display unit in actual situations.

As shown in FIG. 4, the light direct-irradiation region has a surface parallel to the planarization layer 4. The light refraction region has a surface inclined with respect to the planarization layer 4, and the light refraction region is located on both sides of the light direct-irradiation region.

FIG. 5 schematically shows a stereogram of a light-extracting layer in the bottom-emitting OLED display unit shown in FIG. 3, and it can be seen that the light-extracting layer 5 in the present embodiment has an arcuate cross section. Likewise, a length direction of the light-extracting layer 5 is perpendicular to a plane of paper. Thus, both the light direct-irradiation region and the light refraction region have an arcuate surface actually.

The two specific embodiments described above are merely illustrative of the structure of the light-extracting layer 5 as well as the light direct-irradiation region and the light refraction region. it is readily understood that the light-extracting layer 5 may have other preferred structures. For example, as shown in FIG. 6, the light refraction region of the light-extracting layer 5 is arranged in four directions of the light direct-irradiation region. Alternatively, it is possible to use a part of a sphere or ellipsoid as the light-extracting layer. Those skilled in the art can make various changes and modifications in accordance with the embodiments of the present disclosure, without departing from the spirit and essence of the present disclosure.

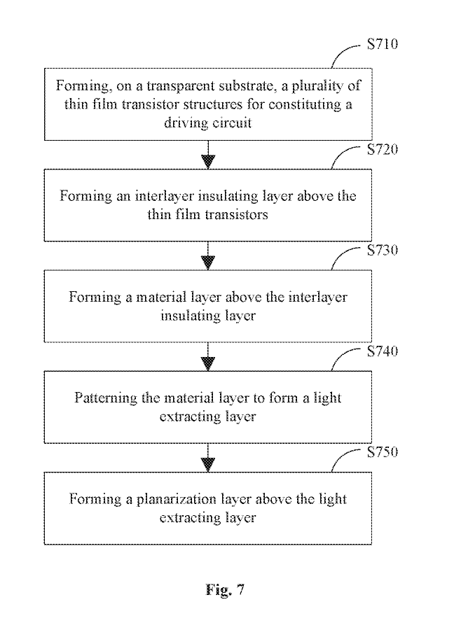

FIG. 7 further shows a method for manufacturing the bottom-emitting OLED display unit. As shown in the figure, the method comprises following steps.

In step S710, a plurality of thin film transistor structures for constituting a driving circuit are formed on a transparent substrate.

In step S720, an interlayer insulating layer is formed above the thin film transistor structures.

In step S730, a material layer is formed above the interlayer insulating layer.

In step S740, the material layer is patterned to form a light-extracting layer.

In step S750, a planarization layer is formed above the light-extracting layer.

It should be noted that the light-extracting layer 5 is manufactured prior to the planarization layer 4. That is, a material layer for forming the light-extracting layer 5 is formed above the formed interlayer insulating layer. A commonly used CVD process can be used for a film formation of the material layer. The material layer is then patterned. The patterning process generally comprises coating a photoresist and exposing and developing the photoresist. Subsequently, the material layer is etched, and finally, the residual photoresist is peeled off The patterning process can be obtained with reference to the prior art, and is not described in detail here.

In addition, in the process of patterning the material layer, a gray tone mask process may be used, and steps of the gray tone mask process are specified according to a specific shape of the light-extracting layer.

In the present embodiment, the light-extracting layer 5 can be formed by only adding one manufacture process prior to the step of making the planarization layer 4 in combination with common treatment means of processing, which improves the light extraction efficiency of the OLED display unit and light utilization efficiency. It is easy to operate, and there is no significant increase in cost.

Although implementation manners disclosed by the present disclosure are as above, the content is only for better understanding of the present disclosure rather than a limitation to the present disclosure. Any one skilled in the art can make any modifications or changes in terms of implementation manners and details without departing from the spirit and essence of the present disclosure, but the patent protection scope of the present disclosure is still subject to the scope defined in the claims.

1. A bottom-emitting OILED display unit, which comprises a transparent substrate, a plurality of thin film transistor structures, disposed on the transparent substrate, for constituting a driving circuit, an interlayer insulating layer and a planarization layer disposed above the thin film transistor structures, and a light-extracting layer disposed between the interlayer insulating layer and the planarization layer, wherein the light-extracting layer is configured such that light projected on a surface thereof is deflected so as to prevent the light from being blocked by the thin film transistor structures.

2. The display unit according to claim 1, wherein a refractive index of a material for manufacturing the light-extracting layer is greater than a refractive index of a material for manufacturing the planarization layer.

3. The display unit according to claim wherein a light transmittance of a material for manufacturing the light-extracting layer is greater than or equal to a light transmittance of a material for manufacturing the planarization layer.

4. The display unit according to claim 1, wherein the light-extracting layer is disposed within a region corresponding to a gap between the plurality of thin film transistor structures.

5. The display unit according to claim 1, wherein
the light-extracting layer comprises a light direct-irradiation region and a light refraction region located at a periphery of the light direct-irradiation region;
wherein a path of light irradiating the light direct-irradiation region does not change or does not change significantly, and a path of light irradiating the light refraction region changes significantly.

6. The display unit according to claim 5, wherein the light direct-irradiation region has a surface parallel to the planarization layer, and the light refraction region has a surface inclined with respect to the planarization layer.

7. The display unit according to claim 5, wherein both the light direct-irradiation region and the light refraction region have an arcuate surface.

8. The display unit according to claim 1, wherein the light-extracting layer is made of an organic material or an inorganic material.

9. A method for manufacturing a bottom-emitting OILED display unit, which comprises:
forming, on a transparent substrate, a plurality of thin film transistor structures for constituting a driving circuit,
forming an interlayer insulating layer above the thin film transistor structures,
forming a material layer above the interlayer insulating layer,
patterning the material layer to form a light-extracting layer, and
forming a planarization layer above the light-extracting layer.

10. The method according to claim 9, wherein the material layer is patterned with a gray tone mask to form the light-extracting layer.
